(19) United States
(12) Patent Application Publication
(10) Pub. No.: US 2007/0298540 A1
(43) Pub. Date: Dec. 27, 2007

(54) Dicing and Packing Metod of Sheet-Like Wafer, Packed Product of Water, and Separation Jig

(75) Inventors: Naoki Tanabe, Kouza-gun (JP); Kohei Yoshidome, Kouza-gun (JP)

Correspondence Address: QUINN EMANUEL;KODA & ANDROLIA, 865 S. FIGUEROA STREET, 10TH FLOOR, LOS ANGELES, CA, 90017, US

(73) Assignee: Toyo Communication Equipment Co., Ltd.

(21) Appl. No.: 11/661,007

(22) PCT Filed: Aug. 30, 2005
(86) PCT No.: PCT/JP05/15794

§ 371 Date: Feb. 23, 2007

(30) Foreign Application Priority Data
Aug. 30, 2004 (JP) 2004-251035

(51) Int. Cl. H01L 21/00; B23P 19/00

(52) U.S. Cl. 438/118; 29/762; 257/E23.001; 257/E21.001; 257/E21.499

(57) ABSTRACT

To provide a dicing and packing method of a sheet-like wafer that can collectively solve conventional problems such as damage of an individual piece, generation of dusts, and increase of troublesome work at a time of packing, caused in a process of packing the individual pieces obtained by dicing a wafer with a large area, and a packed product of a wafer. The method includes a dicing step of, in a state in which a dicing tape 2 has been adhered on one face of a cleaned wafer 1, dicing the wafer into individual pieces from the other face thereof, a thermal separation tape adhering step of adhering a thermal separation tape 3 on the other face of the wafer, a dicing tape peeling step, a heating step of heating the thermal separation tape to decrease an adhesive force thereof, a first protective sheet tape adhering step of adhering a first protective sheet tape 4 on one face of the wafer, a thermal separation tape peeling step, an appearance inspecting step of performing appearance inspection from the other face of the wafer, and a second protective sheet tape adhering step of adhering a second protective sheet tape 5 on the other face of the wafer which has been completed to the appearance inspecting step.

### TECHNICAL FIELD

The present invention relates to an improvement in a method for packing a plurality of optical devices, and in particular to a dicing and packing method of a sheet-like wafer for smoothly implementing a process from dividing a wafer with a large area where a plurality of optical devices have been coupled in a sheet in an unseparated state into individual pieces, to packing a plurality of individual pieces, and to a packed product of a wafer.

### BACKGROUND ART

When plate-shaped or polyhedral optical devices such as a mirror, a wavelength plate, or a prism are manufactured by batch processing using a glass substrate (wafer) with a large area, they are manufactured by performing required processings on individual piece regions at once to complete the optical devices, and dicing the glass substrate to individual pieces of optical devices. The diced optical devices are generally packed in a state in which plural optical devices are arranged and received on a tray made from a PS material or a PET material. A wafer is generally diced by applying a dicing tape on a whole one side face of the wafer, and dividing only the wafer into individual pieces from the other side face of the wafer. After the wafer is diced, individual pieces of optical devices are peeled from the dicing tape and then set on a cleaning tray for cleaning. After the individual pieces are cleaned, an appearance inspection thereof is performed, and the individual pieces are packed in a packing tray to be shipped.

However, in the conventional dicing and packing method described above, since, after dicing, a work for peeling the tape to separate the individual pieces, performing cleaning and appearance inspection, and taking out the individual pieces individually to place them on another packing tray, is performed, the work becomes complicated. Further, it is necessary to prepare packing trays with different receiving portion shapes corresponding to sizes of individual pieces for packing, thereby increasing the number of kinds of packing trays. Furthermore, when a packing tray is used for packing, there is a possibility that an edge of an optical device cuts the tray due to vibrations during transportation of the packing tray, which generates dusts or loosen the individual pieces within the packing tray.

Japanese Patent Application Laid-Open No. 2000-296894 discloses a technique in which a double-sided adhesive tape is attached on an inner bottom face of a lower case in advance when optical devices are received in an aligned state in a packing case, and then the optical devices are adhered on the tape, thereby preventing loosening of the optical devices or generation of dusts due to contact thereof with the tray. In the conventional art, however, after a wafer is cut into individual pieces, it is necessary to set the respective pieces at required portions within the packing case with excellent alignment, which lowers the workability. Further, the optical device generally has directionality and must be preliminarily set in the case such that an optical face and a non-optical face of the optical device can be distinguished from each other when it is taken out of the case to be assembled to an actual machine. However, it is inconvenient to perform such a work for each individual piece.

Japanese Patent Application Laid-Open Nos. 2001-97475 and 2004-10051 disclose techniques in which packing is performed by adhering completed electronic parts or optical devices on an adhesive sheet in a predetermined arrangement to hold them on the adhesive sheet. In both techniques, since it is necessary to adhere the individual electronic parts or optical devices at predetermined positions on the adhesive sheet with excellent alignment, complication of the packing work is not solved. Particularly, it is complicated to perform adhesion work while confirming the directionality of the electronic parts or the optical parts.
Patent Document 1: Japanese Patent Application Laid-Open No. 2000-296894
Patent Document 2: Japanese Patent Application Laid-Open No. 2001-97475
Patent Document 3: Japanese Patent Application Laid-Open No. 2004-10051

### DISCLOSURE OF THE INVENTION

### Problems to be Solving by this Invention

The present invention has been made in view of the above circumstances and an object thereof is to provide a dicing and packing method of a sheet-like wafer that can collectively solve conventional problems such as damage of an individual piece, generation of dusts, and increase of troublesome work at a time of packing, caused in a process of packing the individual pieces obtained by dicing a wafer with a large area, and a packed product of a wafer.

### Means for Solving the Problems

In order to solve the above problems, the invention of claim 1 provides a dicing and packing method of a sheet-like wafer, including: a dicing step of, in a state in which a dicing tape has been adhered to one face of a wafer where a plurality of optical devices have been coupled in sheet in an unseparated state, dicing the wafer to individual pieces from the other face of the wafer; a thermal separation tape adhering step of adhering a thermal separation tape on the other face of the wafer where the dicing tape has not been adhered; a dicing tape peeling step of peeling the dicing tape; a heating step of heating the thermal separation tape adhered on the other face of the wafer to decrease adhesive force thereof; a first protective sheet tape adhering step of adhering a first protective sheet tape on the one face of the wafer; a thermal separation tape peeling step of peeling the thermal separation tape from the other face of the wafer; and a second protective sheet tape adhering step of adhering a second protective sheet tape on the other face of the wafer.

The invention of claim 2 provides the dicing and packing method of a sheet-like wafer according to claim 1, characterized in that, after the second protective sheet tape adhering step, a cushioning material attaching step of attaching a cushioning material on both outer faces of the first and the second protective sheet tapes is implemented.

The invention of claim 3 provides the dicing and packing method of a sheet-like wafer according to claim 1 or 2, characterized in that an adhesive force V1 of the dicing tape, an adhesive force V2 of the thermal separation tape, an adhesive force V3 of the thermal separation tape after being heated, and adhesive forces V4 of the first and the second protective sheet tapes satisfy a relationship of V3<V4<V1<V2.

The invention of claim 4 provides a packed product of a wafer formed by the dicing and packing method of a sheet-like wafer according to claim 1, 2 or 3.

The invention of claim 5 provides a separation jig for peeling an optical device constituting the packed product according to claim 4 manufactured by the method according to claim 1, from a protective sheet tape, the separation jig including: a tape supporting piece that, by completely peeling one protective sheet tape, supports one face of the other protective sheet tape that adheres and holds an optical device group on the other face thereof; and a servicing portion that is provided on the tape supporting piece to valley-fold a proper portion of the other face of the other protective sheet tape.

### Effect of the Invention

According to the invention of claim 1, 3, or 4, after a wafer with a large area that is held on a dicing tape is cut into individual pieces, a packed product where cut individual pieces have been sandwiched in an aligned state between protective sheet tapes having predetermined adhesive forces can be finally manufactured by sequentially and alternately performing an adhering work and a peeling work of other tapes to one face of the wafer without separating the individual pieces to move them. Therefore, a work for individually peeling the individual pieces or moving them can be saved, and a packing work can be conducted efficiently even by an unskilled worker.

According to the invention of claim 2, since a cushioning material is attached on both outer faces of the first and the second protective sheet tapes, when a packed product is boxed, the packed product is prevented from being broken or bent, or an individual piece is prevented from being damaged due to an impact during transportation thereof.

According to the invention of claim 5, a separation jig that efficiently peels the individual pieces from a first packed product can be provided.

### BEST MODE FOR CARRYING OUT THE INVENTION

The present invention will be explained in detail below according to an embodiment with reference to the drawings.

FIGS. 1(a) to 1(j) are process diagrams for explaining a dicing method and a packing method of a sheet-like wafer according to one embodiment of the present invention.

FIG. 1(a) shows a cleaning step of cleaning a wafer 1 in which a plurality of optical devices have been coupled in sheet in an unseparated state The wafer 1 is made of, for example, a glass plate, and optical devices put in an unseparated state can be completed by performing predetermined workings on individual piece regions of the wafer 1 in a batch processing. Examples of the optical device include, for example, a flat plate-like device such as a mirror or a wavelength plate, a cubic device such as a prism, or another optical device that can be manufactured by processing a face of a flat glass plate. Outer faces of the wafer 1 in which completed optical devices have been coupled to one another in sheet (in plate) in an unseparated state are cleaned so that dusts, chemicals, or the like adhered during the working step are removed.

FIG. 1(b) shows a dicing step of, in a state in which a dicing tape 2 has been adhered on one face 1a of the cleaned wafer 1, dicing the wafer 1 to individual pieces from the other face 1b side of the wafer 1, while not dicing the dicing tape 2. A dicing saw (not shown) is used in dicing, and while the wafer 1 is divided into individual pieces of optical devices by cutting the wafer from the other face side thereof lengthwise and crosswise, unnecessary portions except for the optical devices P are cut off. At that time, the dicing tape 2 is cut by a length corresponding to a thickness of the wafer 1 such that it is not damaged as much as possible. However, when cutting dust of the dicing tape is generated to adhere on an optical device, cooling effect at a cutting time is enhanced by setting the revolution speed to a low speed (20000 rpm) at the dicing cutting time, thereby reducing generation and adhesion of the tape dust. An adhesive force of an adhesive layer of the dicing tape 2 is set to, for example, about 1N to 2N/20 mm. Part of the cutting dust generated according to the dicing is captured by the adhesive layer of the dicing tape 2. After the dicing, unnecessary portions except for the optical devices are removed from the dicing tape, so that only the optical devices are left on the tape.

FIG. 1(c) shows a thermal separation tape adhering step of adhering a thermal separation tape 3 on the other face 1b of the wafer 1 on which the dicing tape 2 has not been adhered. In this example, obverse and reverse faces of the wafer 1 put in the state shown in FIG. 1(b) are reversed and the other face 1b is adhered to an adhesive face of the thermal separation tape 3 positioned below. At an adhering time of the thermal separation tape 3, a reverse face of the tape 3 is rubbed by fingers or the like such that the adhesive face of the tape 3 comes in close contact with the other face 1b of the wafer 1. An adhesive force of the adhesive face of the thermal separation tape 3 before being heated is set to, for example, a low adhesion of about 3N/20 mm. When the adhesive force is set to high adhesion, residue of adhesive from the adhesive face occurs on the optical device side, which causes degradation in characteristics of the optical device.

FIG. 1(d) shows a dicing tape peeling step of peeling the dicing tape from the one face 1a of the wafer. When the dicing tape is peeled, the wafer is placed on a working table with the dicing tape being positioned on a lower side, the dicing tape is moved in a direction parallel to the tape face, while being bent as shown in FIG. 1(d), so that the dicing tape is peeled slowly.

FIG. 1(e) shows a heating step of heating the thermal separation tape that is adhered on the other face of the wafer to decrease an adhesive force thereof. At this step, the adhesive force of the adhesive face of the thermal separation tape 3 is largely decreased by placing the thermal separation tape 3 on a heating face of a hot plate 10 to heat the tape up to about 120° C. In this example, the adhesive force is decreased to about 0.1N/20 mm.

FIGS. 2(a) and 2(b) show a constitution of the thermal separation tape and a principle for facilitating to peel a wafer as a member to be adhered to, by heating. That is, the thermal separation tape 3 has an adhesive layer 3b on a base 3a, where thermally foaming microspheres 3c are dispersed evenly within the adhesive layer 3b. In a non-heating state, as shown in FIG. 2(a), the thermally foaming microspheres 3c are held in the adhesive layer 3b, but when heated to a predetermined temperature or higher, as shown in FIG. 2(b), the thermally foaming microspheres 3c foam and expand so as to break through an upper face of the adhesive layer 3b to project upward and push up a lower face of the wafer 1. Thus, the wafer 1 is partially separated from the adhesive layer 3b, so that adhesive force of the adhesive layer is decreased. At that time, since the adhesive force of the adhesive layer 3b itself is not lowered, the state in which the adhesive layer has captured dusts generated during dicing can be maintained.

FIG. 1(f) shows a first protective sheet tape adhering step of adhering a first protective sheet tape 4 on one face 1a of the wafer 1 from which the dicing tape 2 has been peeled. An adhesive force of an adhesive layer of the first protective sheet tape 4 is set to the lowest value, for example, about 0.15N/20 mm. The first protective sheet tape 4 is used in a state in which it has been adhered on the optical devices during packing.

FIG. 1(g) shows a thermal separation tape peeling step of peeling the thermal separation tape 3 from the other face 1b of the wafer 1. At this step, while the wafer is supported on the working table such that the first protective sheet tape 4 is positioned on a lower side, the thermal separation tape 3 with a decreased adhesive force is peeled by pulling the thermal separation tape 3 in a direction parallel to an upper face of the wafer while bending the tape, as shown in FIG. 1(g). At that time, all foreign materials such as cutting dust generated during the dicing are removed together with the thermal separation tape 3. Accordingly, the foreign materials do not adhere to the first protective sheet tape side either.

FIG. 1(h) shows an appearance inspecting step of performing appearance inspection from the other face 1b of the wafer on which the first protective sheet tape 4 is not adhered using a microscope. As the result of appearance inspection, an optical device P identified as a defective product is removed from the first protective sheet tape 4, and only non-defective products are left thereon. The number of optical devices which are left as non-defective products are confirmed.

FIG. 1(i) shows a second protective sheet tape adhering step of adhering a second protective sheet tape 5 on the other face 1b of the wafer of which the appearance inspecting step is completed. An adhesive layer of the second protective sheet tape 5 is brought in close contact with the other face 1b of the wafer 1 on the first protective sheet tape 4 on which optical devices P identified as non-defective products are left so that the second protective sheet tape 5 is adhered to the wafer 1. Thus, an optical device group (wafer) including only non-defective products is held in a state of being supported through adhesion at both faces thereof by the first and the second protective sheet tapes, so that the optical devices are not separated unless both the tapes are peeled. A code A indicates a first packed product (packed product of wafer) obtained in this manner. The quality of material and the adhesive force of the adhesive layer of the second protective sheet tape 5 are equivalent to those of the first protective sheet tape 4.

In the series of dicing and packing steps as described above, since the respective optical devices constituting the wafer 1 do not change in its orientations and do not deviate at all, when individual optical devices are to be taken out of the first packed product A finally obtained, after one protective sheet tape is peeled, the optical devices held on the other protective sheet tape is taken out individually, so that directionality of the optical device can be confirmed easily.

Next, FIG. 1(j) shows a cushioning material attaching step of, after the second protective sheet tape adhering step, attaching a cushioning material 6 (a cardboard plate, a pasteboard, a mirror mat, another cushioning plate, or the like) to both outer faces of the first and the second protective sheet tapes 4 and 5 to protect the first packed product A in a sandwiching manner. By using a plate member with a predetermined rigidity as the cushioning material 6, deformation such as bending or curvature of the first packed product A can be eliminated. Second packed products B, each obtained by sandwiching the first packed product A by the cushioning materials 6 in this manner, can be stacked in a cardboard box (not shown) or the like to be packed. Since the optical device group sandwiched between the respective protective sheet tapes 4 and 5 to be protected is further protected from the outside by the cushioning materials 6, it is protected from vibrations, impact or other external forces. Particularly, since optical devices do not directly collide against or slide on a hard object such as a resin tray as in the conventional example, problems of damages on the optical devices or generation of dusts from the tray during a transportation or a transfer is solved. Since a work for separating cut optical parts to move them on a tray, which should be performed from dicing of the wafer to completion of the packed product, is not required at all, workability is not only improved but also a work for confirming directionality of the optical devices during movement thereof becomes unnecessary, so that working efficiency is further improved.

By setting an adhesive force V1 of the dicing tape, an adhesive force V2 of the thermal separation tape, an adhesive force V3 of the heated thermal separation tape, and an adhesive forces V4 of the first and the second protective sheet tapes to satisfy a relationship of V3<V4<V1<V2, adhesion and removal of dusts performed by the tapes 2 and 3 in the series of the step as described above, a peeling work of the tapes 2 and 3 on which dusts have been adhered, and a peeling work for peeling either of the protective sheet tapes after the first packed product A has been produced can be performed reliably and smoothly.

FIGS. 3(a) to 3(e) show a working procedure for taking individual optical devices P from the packed product A of a wafer completed with reference to FIG. 1(i).

A separation jig 20 shown in FIG. 3(d) is means for peeling the optical devices P constituting the first packed product A from the protective sheet tape. The separation jig 20 includes a tape supporting piece 21 that, by peeling one protective sheet tape 5 completely, supports one face of the other protective sheet tape 4 having the optical device P group adhered and held on the other face thereof, and a servicing portion 22 for valley-folding a proper portion of the other face of the other protective sheet tape is provided on the tape supporting piece 21. The separation jig 20 according to this embodiment is constituted by coupling two plate members 21a and 21b in a dogleg shape, and a bent portion coupling both the plate members 21a and 21b at a predetermined angle serves as the servicing portion 22.

First, a first packed product A shown in FIG. 3(a) is set and the second protective sheet tape 5 on the upper side is peeled from an upper face of the wafer 1 (optical device group) as shown in FIG. 3(b). At that time, a separation direction is determined such that a folding angle of a separation portion of the second protective sheet tape 5 is maintained at an acute angle (within an angle of 30°). By adopting such a separation direction, individual optical devices P are not peeled from the first protective sheet tape 4 positioned on the lower side, so that only the second protective sheet tape 5 can be peeled.

FIG. 3(c) shows a state in which separation has been completed. At a peeling step shown in FIG. 3(d), a back face of the first protective sheet tape 4 is brought in close contact with an upper face of the supporting piece 21 so as to extend across upper faces of both the plate members 21a and 21b, and the first protective sheet tape 4 is positioned such that optical devices (row) P1 to be peeled are put on a top of the folded servicing portion 22. At that time, the optical devices P1 are picked up while separation of the optical devices P1 from the tape is promoted by stretching portions of the protective sheet tape 4 positioned in front and behind the optical devices P1 to be peeled.

FIG. 3(e) shows another embodiment of the separation jig 20, in which a flat plate-like tape supporting piece 26 is erectly provided at a right angle on a base 25, and a top of the tape supporting piece 26 functions as a servicing portion 27. When optical devices P are peeled from the first protective sheet tape 4 shown in FIG. 3(c) using the separation jig 20, optical devices (row) P1 to be peeled are positioned on the servicing portion 27 in a state in which a back face of the first protective sheet tape 4 is attached to one face of the tape supporting piece 26, as shown in FIG. 3(e). At that time, separation of the optical devices is facilitated by applying tension on the first protective sheet tape on front and back of the optical devices P1 such that the protective sheet tape is stretched. In that state, when the optical devices P1 are picked up in a direction of arrow, separation is completed.

FIGS. 4(a) to 4(c) show a state in which the second packed product B is finally packed to be shipped.

A sectional view and a plan view of FIG. 4(a) show a packed product C obtained by wrapping the second packed product B with a wrapping material 31 in a state in which other cushioning materials 30 are respectively attached on both upper and lower faces of the second packed product B, and binding the outside of the wrapped material using rubber bands 32. The packed product C itself may be an object to be transported or transferred, or a plurality of stacked packed products may be packed.

FIG. 4(b) shows a state in which the packed products C shown in FIG. 4(a) have been wrapped by a plastic bag 35 in a state in which the packed products C have been vertically stacked in a multistage. When a plurality of packed products C are packed together, handling can be facilitated by vertically packing the packed products in a multistage, and then packing the them by using any kind of final packing means 35.

FIG. 4(c) shows another example of a final packed mode, in which the second packed products B shown in FIG. 1(j) are wrapped by the wrapping material 31 in a state that the products have been stacked in a multistage via cushioning materials 33 such as a mirror mat, a multi-staged stacked body wrapped by the wrapping material 31 has been bundled by a rubber band 32, and is then finally packed by the plastic bag 35. Thus, the packing work is further facilitated.

The manufacturing method of the present invention can be applied to not only optical parts but also parts manufactured according to a batch processing using a flat plate-like wafer, for example, piezoelectric oscillating elements such as crystal oscillating elements, or other electronic parts.

### BRIEF DESCRIPTION OF THE DRAWINGS

FIGS. 1(a) to 1(j) are process diagrams for explaining a dicing method and a packing method of a sheet-like wafer according to one embodiment of the present invention.

FIGS. 2(a) and 2(b) are explanatory diagrams of a thermal separation tape.

FIGS. 3(a) to 3(e) are explanatory diagrams of a working procedure for taking individual optical devices P from a packed product A of a wafer completed with reference to FIG. 1(i).

FIGS. 4(a) to 4(c) are diagrams showing a state in which a second packed product B is finally packed to be shipped.

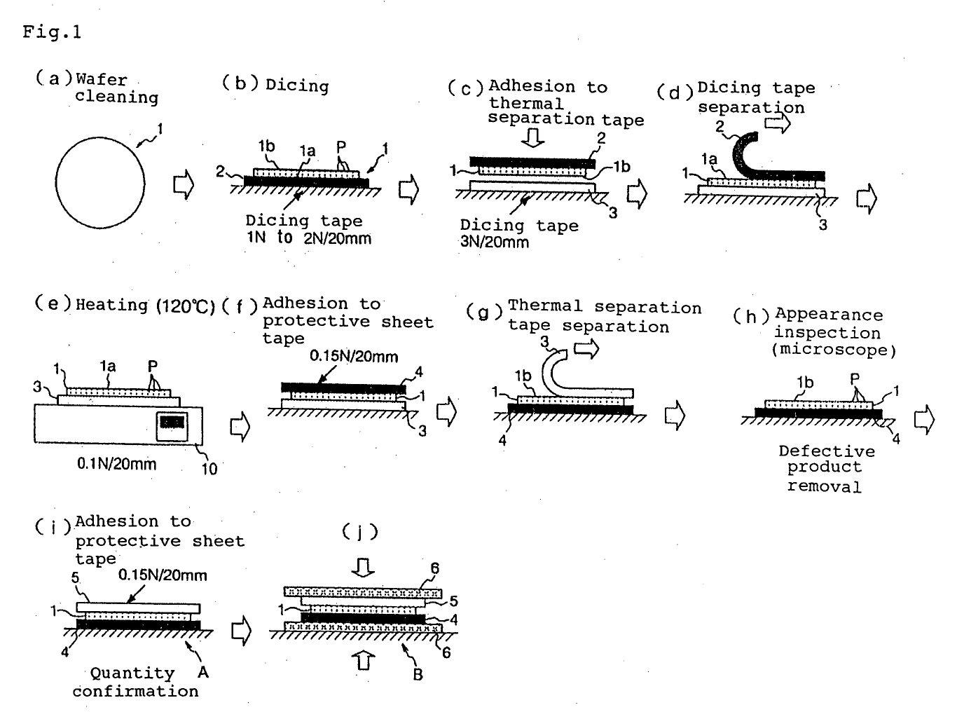

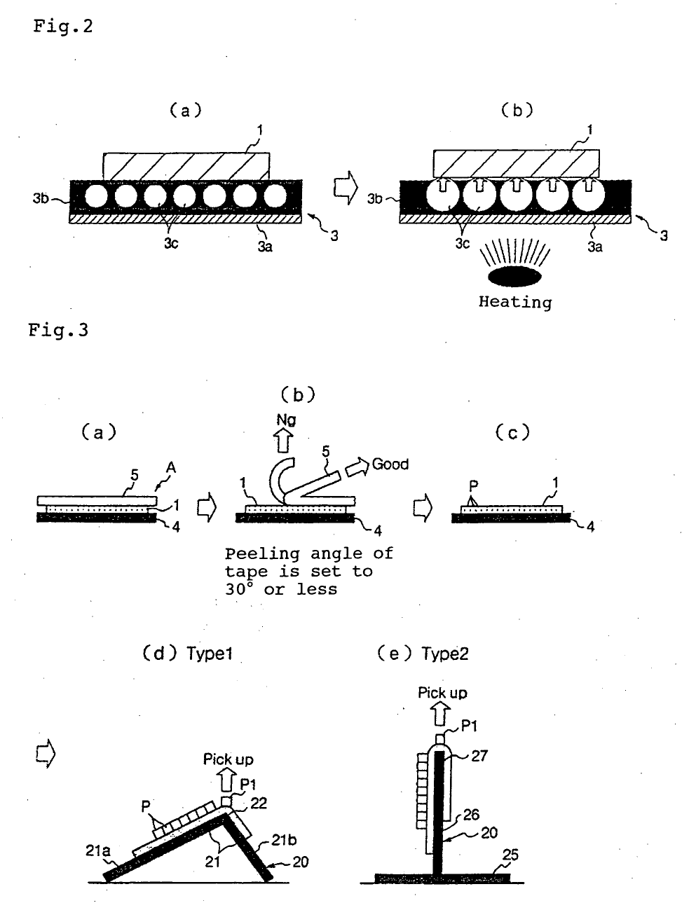

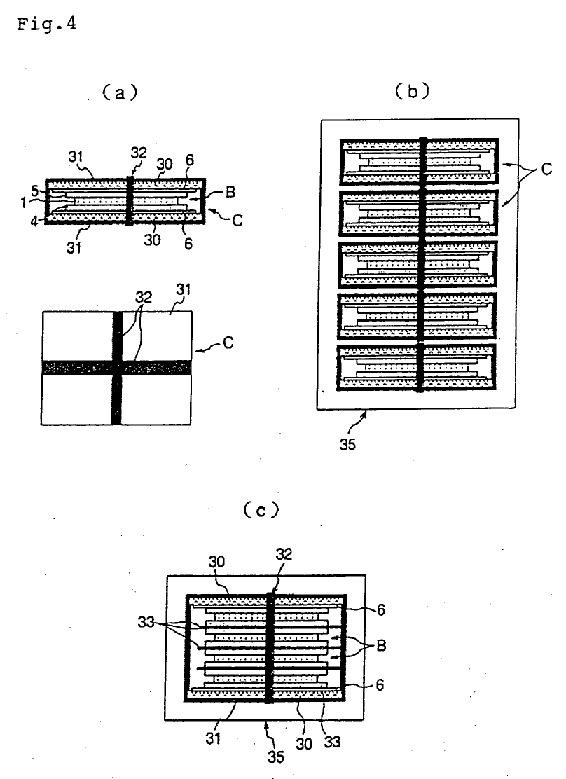

### EXPLANATION OF THE CODES

1 Wafer, 1a One face, 1b other face, 2 Dicing tape, 3 Thermal separation tape, 3a Base, 3b Adhesive layer, 3c Thermally foaming microsphere, 4 First protective sheet tape, 5 Second protective sheet tape, 6 Cushioning material, 10 Hot plate (heating unit), A, B, C Packed product, 20 Separation jig, 21 Tape supporting piece, 22 Servicing portion.

1. A dicing and packing method of a sheet-like wafer, comprising: a dicing step of, in a state in which a dicing tape has been adhered to one face of a wafer where a plurality of optical devices have been coupled in sheet in an unseparated state, dicing the wafer to individual pieces from the other face of the wafer; a thermal separation tape adhering step of adhering a thermal separation tape on the other face of the wafer where the dicing tape has not been adhered; a dicing tape peeling step of peeling the dicing tape; a heating step of heating the thermal separation tape adhered on the other face of the wafer to decrease adhesive force thereof; a first protective sheet tape adhering step of adhering a first protective sheet tape on the one face of the wafer; a thermal separation tape peeling step of peeling the thermal separation tape from the other face of the wafer; and a second protective sheet tape adhering step of adhering a second protective sheet tape on the other face of the wafer.

2. The dicing and packing method of a sheet-like wafer according to claim 1, wherein, after said second protective sheet tape adhering step, a cushioning material attaching step of attaching a cushioning material on both outer faces of the first and the second protective sheet tapes is implemented.

3. The dicing and packing method of a sheet-like wafer according to claim 1 or 2, wherein an adhesive force V1 of said dicing tape, an adhesive force V2 of the thermal separation tape, an adhesive force V3 of the thermal separation tape after being heated, and adhesive forces V4 of the first and the second protective sheet tapes satisfy a relationship of V3<V4<V1<V2.

4. A packed product of a wafer formed by the dicing and packing method of a sheet-like wafer according to claim 1 or 2.

5. A separation jig for peeling an optical device constituting the packed product according to claim 4 manufactured by the method according to claim 1, from a protective sheet tape, the separation jig comprising: a tape supporting piece that, by completely peeling one protective sheet tape, supports one face of the other protective sheet tape that adheres and holds an optical device group on the other face thereof; and a servicing portion that is provided on the tape supporting piece to valley-fold a proper portion of the other face of the other protective sheet tape.

6. A packed product of a wafer formed by the dicing and packing method of a sheet-like wafer according to claim 3.

7. A separation jig for peeling an optical device constituting the packed product according to claim 6 manufactured by the method according to claim 1, from a protective sheet tape, the separation jig comprising: a tape supporting piece that, by completely peeling one protective sheet tape, supports one face of the other protective sheet tape that adheres and holds an optical device group on the other face thereof; and a servicing portion that is provided on the tape supporting piece to valley-fold a proper portion of the other face of the other protective sheet tape.
